(19) United States
(12) Patent Application Publication
(10) Pub. No.: US 2009/0045862 A1
(43) Pub. Date: Feb. 19, 2009

(54) CLOCK GENERATING CIRCUIT OF SEMICONDUCTOR MEMORY APPARATUS

(75) Inventors: Yong Ju Kim, Ichon (KR); Kun Woo Park, Ichon (KR); Dae Han Kwon, Ichon (KR); Hee Woong Song, Ichon (KR); Ic Su Oh, Ichon (KR); Hyung Soo Kim, Ichon (KR); Tae Jin Hwang, Ichon (KR); Hae Rang Choi, Ichon (KR); Ji Wang Lee, Ichon (KR)

Correspondence Address: BAKER & MCKENZIE LLP;PATENT DEPARTMENT, 2001 ROSS AVENUE, SUITE 2300, DALLAS, TX, 75201, US

(73) Assignee: HYNIX SEMICONDUCTOR, INC., Ichon (KR)

(21) Appl. No.: 12/167,066

(22) Filed: Jul. 2, 2008

(30) Foreign Application Priority Data
Aug. 13, 2007 (KR) 10-2007-0081025

(51) Int. Cl. H03K 4/00

(52) U.S. Cl. 327/256

(57) ABSTRACT

A clock generating circuit of a semiconductor memory apparatus includes a phase splitter that delays a clock to generate a delayed clock and inverts the clock to generate an inverted clock, and a clock buffer that buffers the delayed clock and the inverted clock and outputs a rising clock and a falling clock.

### CROSS-REFERENCES TO RELATED APPLICATION

The present application claims priority under 35 U.S.C. 119(a) to Korean Patent Application number 10-2007-0081025, filed on Aug. 13, 2007, in the Korean Intellectual Property Office, the contents of which are incorporated herein by reference in their entirety as if set forth in full.

### BACKGROUND

1. Technical Field

The embodiments described herein relate to a semiconductor memory apparatus, and more particularly, to a clock generating circuit that generates a clock in a semiconductor memory apparatus.

2. Related Art

In general, conventional Double Data Rate (DDR) Dynamic Random Access Memories (DRAMs) use a rising clock and a falling clock for data input/output. FIG. 1 is a diagram illustrating a conventional clock generating circuit 1 that can be included in such a conventional DDR DRAM. As can be seen, the clock generating circuit 1, which generates the rising clock and the falling clock includes first to third inverters IV1 to IV3 and a delay.

A clock signal ‘CLK’ passes through the first inverter IV1 and the second inverter IV2 in order to generate a rising clock signal ‘RCLK’. In the clock generating circuit 1, the clock signal ‘CLK’ also passes through the delay and the third inverter IV3 in order to generate a falling clock signal ‘FCLK’. The delay is used to synchronize the transition timing of the rising clock signal ‘RCLK’ with the transition timing of the falling clock signal ‘FCLK’.

A clock generating circuit having the structure shown in FIG. 1 is greatly affected by variation in P.V.T (process, voltage, and temperature). That is, a large variation in the phase difference between the rising clock signal ‘RCLK’ and the falling clock signal ‘FCLK’ occurs due to the variation in P.V.T, which makes it difficult to apply the circuit to DRAMs requiring a high processing rate.

In general, as shown in FIG. 2, the clock generating circuit outputs the rising clock signal ‘RCLK’ and the falling clock signal ‘FCLK’ to a plurality of internal circuits 2, 3, 4, and 5. When the rising clock signal ‘RCLK’ and the falling clock signal ‘FCLK’ generated by the clock generating circuit 1 reach the internal circuits 2, 3, 4, and 5, the transition timing of the two clocks are more likely to deviate from each other as the length of the associated transmission lines increases.

### SUMMARY

A clock generating circuit of a semiconductor memory apparatus capable of preventing the transition timing of a rising clock signal and a falling clock signal from deviating from each other due to variation in P.V.T and a long transmission distance is described herein.

According to one aspect, there is provided a clock generating circuit of a semiconductor memory apparatus. The clock generating circuit includes a phase splitter configured to delay a clock signal to generate a delayed clock signal and invert the clock signal to generate an inverted clock signal, and a clock buffer that buffers the delayed clock signal and the inverted clock signal and outputs a rising clock signal and a falling clock signal.

These and other features, aspects, and embodiments are described below in the section entitled “Detailed Description.”

### BRIEF DESCRIPTION OF THE DRAWINGS

Features, aspects, and embodiments are described in conjunction with the attached drawings, in which:

FIG. 1 is a diagram illustrating the detailed structure of a conventional clock generating circuit of a general semiconductor memory apparatus.

FIG. 2 is a block diagram illustrating a semiconductor memory apparatus to which the general clock generating circuit of FIG. 1 is applied.

FIG. 3 is a block diagram illustrating a clock generating circuit of a semiconductor memory apparatus according to one embodiment.

FIG. 4 is a diagram illustrating the detailed structure of a phase splitter included in the clock generating circuit shown in FIG. 3.

FIG. 5 is a diagram illustrating the detailed structure of a clock buffer included in the clock generating circuit shown in FIG. 3.

FIG. 6 is a diagram illustrating the detailed structure of a comparing unit included in the clock buffer shown in FIG. 5.

FIG. 7 is a timing chart illustrating the operation of the clock generating circuit of FIG. 1.

FIG. 8 is a block diagram illustrating a semiconductor memory apparatus to which the clock generating circuit of FIG. 1 can be applied.

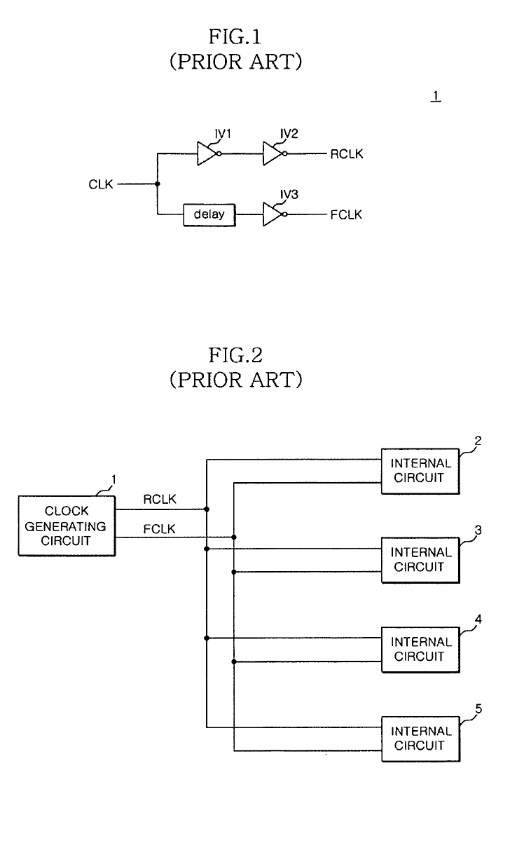

### DETAILED DESCRIPTION

According to the embodiments described herein, a clock generating circuit of a semiconductor memory apparatus can prevent the transition timing of a rising clock signal and a falling clock signal from deviating from each other, regardless of variation in P.V.T and a transmission distance. As a result, it is possible to improve the operational reliability of the semiconductor memory apparatus.

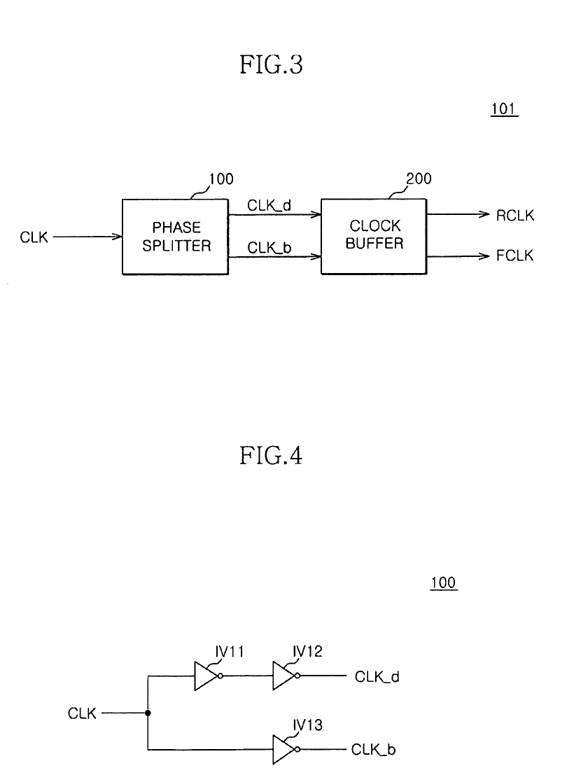

As shown in FIG. 3, a clock generating circuit 101 of a semiconductor memory apparatus configured in accordance with the embodiments described herein can include a phase splitter 100 and a clock buffer 200.

The phase splitter 100 can be configured to receive a clock signal ‘CLK’ and generate a delayed clock signal ‘CLK_d’ and an inverted clock signal ‘CLK_b’. For example, the phase splitter 100 can be configured to delay the clock signal ‘CLK’ to generate the delayed clock signal ‘CLK_d’. The phase splitter 100 can also be configured to invert the clock signal ‘CLK’ to generate the inverted clock signal ‘CLK_b’.

The clock buffer 200 can be configured to buffer the delayed clock signal ‘CLK_d’ and the inverted clock signal ‘CLK_b’ to generate a rising clock signal ‘RCLK’ and a falling clock signal ‘FCLK’, respectively. For example, the clock buffer 200 can buffer the delayed clock signal ‘CLK_d’ to generate the rising clock signal ‘RCLK’. The clock buffer 200 can also buffer the inverted clock signal ‘CLK_b’ to generate the falling clock signal ‘FCLK’.

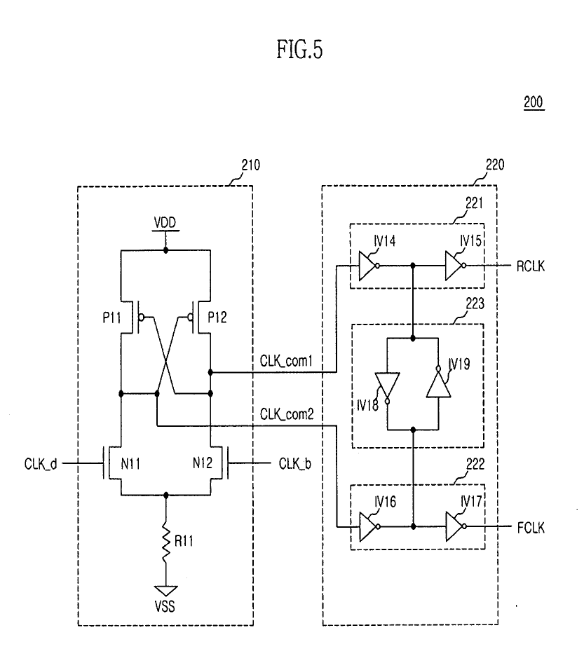

As shown in FIG. 4, the phase splitter 100 can include first to third inverters IV1, IV2, and IV3. The first inverter IV1 can be configured to receive the clock signal ‘CLK’. The second inverter IV2 can receive an output signal from the first inverter IV1 and output the delayed clock signal ‘CLK_d’. The third inverter IV3 can receive the clock signal ‘CLK’ and output the inverted clock signal ‘CLK_b’.

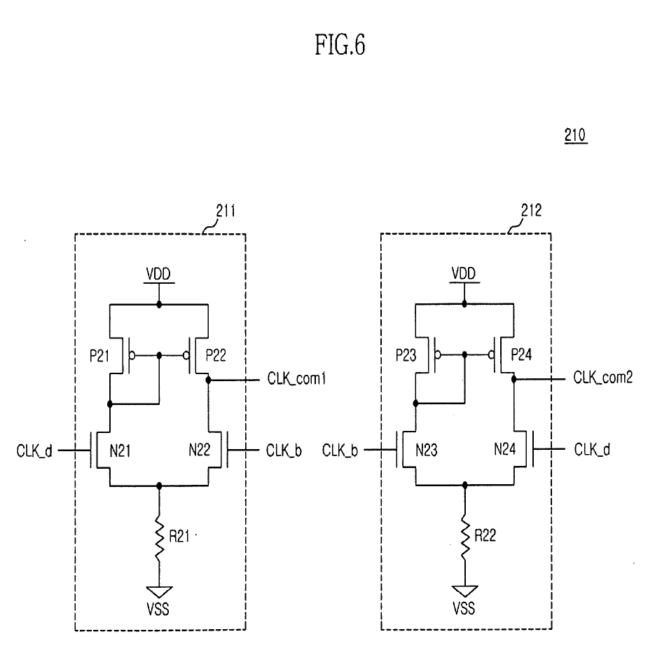

As shown in FIG. 5, the clock buffer 200 can include a comparing unit 210 and a buffering unit 220. The comparing unit 210 can be configured to compare the voltage level of the delayed clock signal ‘CLK_d’ with the voltage level of the inverted clock signal ‘CLK_b’ and generate a first comparison clock signal ‘CLK_com1’ and a second comparison clock signal ‘CLK_com2’.

When the voltage level of the delayed clock signal ‘CLK_d’ is higher than that of the inverted clock signal ‘CLK_b’, then the comparing unit 210 can generate the first comparison clock signal ‘CLK_com1’ having a high level and the second comparison clock signal ‘CLK_com2’ having a low level. When the voltage level of the delayed clock signal ‘CLK_d’ is lower than that of the inverted clock signal ‘CLK_b’, then the comparing unit 210 can generate the first comparison clock signal ‘CLK_com1’ having a low level and the second comparison clock signal ‘CLK_com2’ having a high level.

The comparing unit 210 can comprise, e.g., a differential amplifier. When such is the case, then the comparing unit 210 can include first to fourth transistors P11, P12, N11, and N12, and a first resistive element R11. The first transistor P11 can include a source that is supplied with a power supply voltage VDD. The second transistor P12 can include a source that is supplied with the power supply voltage VDD. The third transistor N11 can include a gate that receives the delayed clock signal ‘CLK_d’ and a drain that is connected to a node where the drain of the first transistor P11 is connected to the gate of the second transistor P12. The fourth transistor N12 can include a gate that receives the inverted clock signal ‘CLK_b’ and a drain that is connected to a node where the drain of the second transistor P12 is connected to the gate of the first transistor P11. The first resistive element R11 can have one end connected to a node where the source of the third transistor N11 is connected to the source of the fourth transistor N12 and another end that is connected to a ground terminal VSS.

In this case, the first comparison clock signal ‘CLK_com1’ can be output from a node where the gate of the first transistor P11, the drain of the second transistor P12, and the drain of the fourth transistor N12 are commonly connected. The second comparison clock signal ‘CLK_com2’ can be output from a node where the drain of the first transistor P11, the gate of the second transistor P12, and the drain of the third transistor N11 are commonly connected.

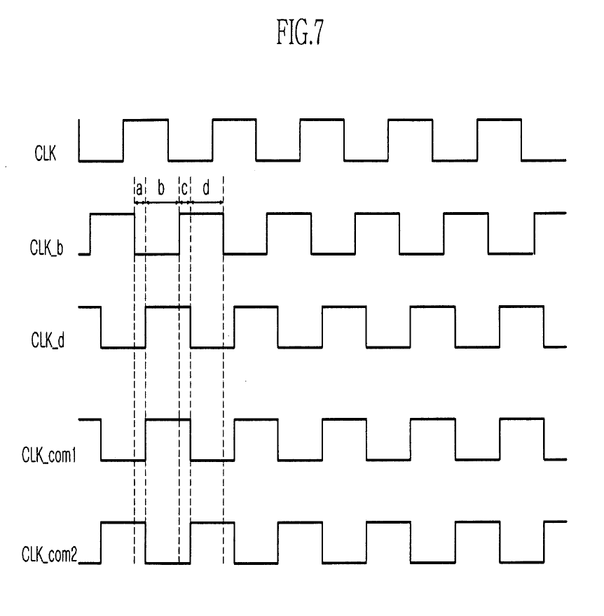

As shown in FIG. 6, the comparing unit 210 can include a first comparator 211 and a second comparator 212.

When the voltage level of the delayed clock signal ‘CLK_d’ is higher than that of the inverted clock signal ‘CLK_b’, then the first comparing unit 211 can generate the first comparison clock signal ‘CLK_com1’ having a high level. When the voltage level of the delayed clock signal ‘CLK_d’ is lower than that of the inverted clock signal ‘CLK_b’, then the first comparing unit 211 can generate the first comparison clock signal ‘CLK_com1’ having a low level.

The first comparator 211 can include fifth to eighth transistors P21, P22, N21, and N22, and a second resistive element R21. The fifth transistor P21 can have a source that is supplied with the power supply voltage VDD. The sixth transistor P22 can have a source that is supplied with the power supply voltage VDD and a gate that is connected to the gate of the fifth transistor P21. The seventh transistor N21 can have a gate that receives the delayed clock signal ‘CLK_d’ and a drain that is connected to a node where the gate of the fifth transistor P21, the gate of the sixth transistor P22, and the drain of the fifth transistor P21 are commonly connected. The eighth transistor N22 can have a drain that is connected to the drain of the sixth transistor P22 and a gate that receives the inverted clock signal ‘CLK_b’. The second resistive element R21 can have one end that is connected to a node where the source of the seventh transistor N21 and the source of the eighth transistor N22 are connected to each other, and another end that is connected to the ground terminal VSS. In this case, the first comparison clock signal ‘CLK_com1’ can be output from a node where the drain of the sixth transistor P22 and the drain of the eighth transistor N22 are connected to each other.

When the voltage level of the delayed clock signal ‘CLK_d’ is higher than that of the inverted clock signal ‘CLK_b’, then the second comparing unit 212 can generate the second comparison clock signal ‘CLK_com2’ having a low level. When the voltage level of the delayed clock signal ‘CLK_d’ is lower than that of the inverted clock signal ‘CLK_b’, then the second comparing unit 212 can generate the second comparison clock signal ‘CLK_com2’ having a high level.

The second comparator 212 can include ninth to twelfth transistors P23, P24, N23, and N24 and a third resistive element R22. The ninth transistor P23 can have a source that is supplied with the power supply voltage VDD. The tenth transistor P24 can have a source that is supplied with the power supply voltage VDD and a gate that is connected to the gate of the ninth transistor P23. The eleventh transistor N23 can have a gate that receives the inverted clock signal ‘CLK_b’ and a drain that is connected to a node where the gate of the ninth transistor P23, the gate of the tenth transistor P24, and the drain of the ninth transistor P23 are commonly connected. The twelfth transistor N24 can have a drain that is connected to the drain of the tenth transistor P24 and a gate that receives the delayed clock signal ‘CLK_d’. The third resistive element R22 can have one end that is connected to a node where the source of the eleventh transistor N23 and the source of the twelfth transistor N24 are connected to each other and the other end that is connected to the ground terminal VSS. In this case, the second comparison clock signal ‘CLK_com2’ can be output from a node where the drain of the tenth transistor P24 and the drain of the twelfth transistor N24 are connected to each other.

Referring to FIG. 5, the buffering unit 220 can be configured to buffer the first comparison clock signal ‘CLK_com1’ and output the rising clock signal ‘RCLK’. The buffering unit 220 can also be configured to buffer the second comparison clock signal ‘CLK_com2’ and output the falling clock signal ‘FCLK’.

The buffering unit 220 can include a first buffer 221 and a second buffer 222. It can further include a transition unit 223.

The first buffer 221 can buffer the first comparison clock signal ‘CLK_com1’ and output the rising clock signal ‘RCLK’.

The first buffer 221 can include fourth and fifth inverters IV14 and IV15. The fourth inverter IV14 can receive the first comparison clock signal ‘CLK_com1’. The fifth inverter IV15 can receive an output signal from the fourth inverter IV14 and output the rising clock signal ‘RCLK’.

The second buffer 222 can be configured to buffer the second comparison clock signal ‘CLK_com2’ and output the falling clock signal ‘FCLK’.

The second buffer 222 can include sixth and seventh inverters IV16 and IV17. The sixth inverter IV16 can receive the second comparison clock signal ‘CLK_com2’. The seventh inverter IV17 can receive an output signal from the sixth inverter IV16 and output the falling clock signal ‘FCLK’.

When either the level of the first comparison clock signal ‘CLK_com1’ or the level of the second comparison clock signal ‘CLK_com2’ transitions, then the transition unit 223 can be configured to enable the simultaneous transition of the rising clock signal ‘RCLK’ and the falling clock signal ‘FCLK’.

The transition unit 223 can include eighteenth and nineteenth inverters IV18 and IV19. An input terminal of the eighteenth inverter IV18 and an output terminal of the nineteenth inverter IV19 can be commonly connected to the node where the fourth inverter IV14 and the fifth inverter IV15 are connected to each other in the first buffer 221. An output terminal of the eighteenth inverter IV18 and an input terminal of the nineteenth inverter IV19 can be commonly connected to the node where the sixth inverter IV16 and the seventh inverter IV17 are connected to each other in the second buffer 222.

Next, the operation of the clock generating circuit 101 of the semiconductor memory apparatus will be described in accordance with one embodiment.

First, the phase splitter 100 delays the clock signal ‘CLK’ to generate the delayed clock signal ‘CLK_d’. The phase splitter 100 inverts the clock signal ‘CLK’ to generate the inverted clock signal ‘CLK_b’.

If the voltage level of the delayed clock signal ‘CLK_d’ is higher than that of the inverted clock signal ‘CLK_b’, then the clock buffer 200 generates the first comparison clock signal ‘CLK_com1’ having a high level and the second comparison clock signal ‘CLK_com2’ having a low level. On the other hand, if the voltage level of the delayed clock signal ‘CLK_d’ is lower than that of the inverted clock signal ‘CLK_b’, then the clock buffer 200 generates the first comparison clock signal ‘CLK_com1’ having a low level and the second comparison clock signal ‘CLK_com2’ having a high level.

This will be described in detail with reference to FIG. 7. In a section (a) where the inverted clock signal ‘CLK_b’ is at a low level and the delayed clock signal ‘CLK_d’ is at a low level, then the first comparison clock signal ‘CLK_com1’ is at a low level and the second comparison clock signal ‘CLK_com2’ is at a high level. This is because the voltage level of the delayed clock signal ‘CLK_d’ is lower than that of the inverted clock signal ‘CLK_b’ before the section (a).

In a section (b) where the inverted clock signal ‘CLK_b’ is at a low level and the delayed clock signal ‘CLK_d’ is at a high level, the first comparison clock signal ‘CLK_com1’ is at a high level and the second comparison clock signal ‘CLK_com2’ is at a low level. This is because the voltage level of the delayed clock signal ‘CLK_d’ is higher than that of the inverted clock signal ‘CLK_b’ in the section (b).

In a section (c) where the inverted clock signal ‘CLK_b’ is at a high level and the delayed clock signal ‘CLK_d’ is at a high level, the first comparison clock signal ‘CLK_com1’ is at a high level and the second comparison clock signal ‘CLK_com2’ is at a low level. This is because the first comparison clock signal ‘CLK_com1’ is at the high level and the second comparison clock signal ‘CLK_com2’ is at the low level in the section (b).

In a section (d) where the inverted clock signal ‘CLK_b’ is at a high level and the delayed clock signal ‘CLK_d’ is at a low level, the first comparison clock signal ‘CLK_com1’ is at a low level and the second comparison clock signal ‘CLK_com2’ is at a high level. This is because the voltage level of the delayed clock signal ‘CLK_d’ is lower than that of the inverted clock signal ‘CLK_b’.

In the sections (a) and (c), that is, when the inverted clock signal ‘CLK_b’ and the delayed clock signal ‘CLK_d’ have the same voltage level, then the comparing unit 200 maintains the output levels before the section where the inverted clock signal ‘CLK_b” and the delayed clock signal ‘CLK_d’ have the same voltage level.

In such an embodiment, the clock generating circuit 101 includes one phase splitter and one clock buffer, but the embodiments described herein are not limited thereto. For example, in another embodiment, a clock generating circuit 101 can include one phase splitter and a plurality of clock buffers sharing the phase splitter.

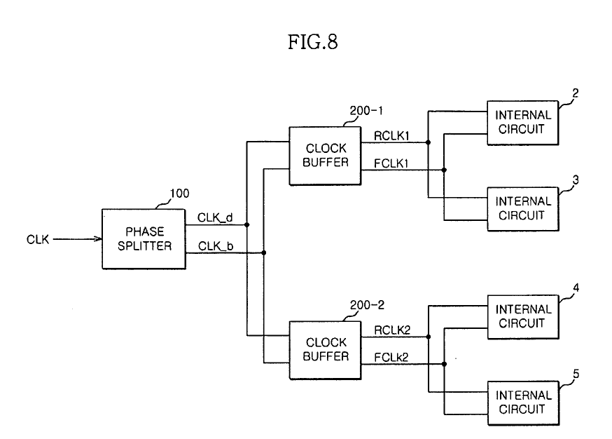

That is, as shown in FIG. 8, one phase splitter can be shared by two clock buffers.

Referring to FIG. 8, a first rising clock signal ‘RCLK’1 output from a first clock buffer 200-1 and a second rising clock signal ‘RCLK’2 output from a second clock buffer 200-2 have the same phase. A first falling clock signal ‘FCLK1’ output from the first clock buffer 200-1 and a second falling clock signal ‘FCLK2’ output from the second clock buffer 200-2 can have the same phase. This is because the first clock buffer 200-1 and the second clock buffer 200-2 can have the same internal structure. The first clock buffer 200-1 and the second clock buffer 200-2 shown in FIG. 8 can have the same internal structure as the clock buffer 200 shown in FIG. 3.

In a conventional semiconductor memory apparatus, e.g., as shown in FIG. 2, the rising clock signal ‘RCLK’ and the falling clock signal ‘FCLK’ output from the clock generating circuit 1 are input to internal circuits 2, 3, 4, and 5. As the distance from the clock generating circuit 1 increases, the internal circuit is more likely to receive the rising clock signal ‘RCLK’ and the falling clock signal ‘FCLK’ whose transition timings deviate from each other.

However, as shown in FIG. 3, in the clock generating circuit 101, the phase splitter 100 can be separated from the clock buffer 200. In addition, as shown in FIG. 8, one phase splitter 100 can be shared by two clock buffers 200-1 and 200-2 [symbol] . Therefore, the first rising clock signal ‘RCLK1’ and the first falling clock signal ‘FCLK1’ output from the first clock buffer 200-1 can be input to the first internal circuit 2 and the second internal circuit 3. In addition, the second rising clock signal ‘RCLK2’ and the second falling clock signal ‘FCLK2’ output from the second clock buffer 200-2 can be input to the third internal circuit 4 and the fourth internal circuit 5. In this way, it is possible to transmit to the internal circuits 2, 3, 4, and 5 a rising clock and a falling clock having the same transition timing, without being affected by the transmission distance of clocks, by providing the clock buffers before the internal circuits requiring the rising clock and the falling clock.

While certain embodiments have been described above, it will be understood that the embodiments described are by way of example only. Accordingly, the apparatus and methods described herein should not be limited based on the described embodiments. Rather, the apparatus and methods described herein should only be limited in light of the claims that follow when taken in conjunction with the above description and accompanying drawings.

What is claimed is:

1. A clock generating circuit of a semiconductor memory apparatus, comprising:
a phase splitter configured to delay a clock signal to generate a delayed clock signal and to invert the clock signal to generate an inverted clock signal; and
a clock buffer coupled with the phase splitter, the clock buffer configured to buffer the delayed clock signal and the inverted clock signal and to output a rising clock signal and a falling clock signal.

2. The clock generating circuit of claim 1, wherein the clock buffer includes:
a comparing unit configured to compare the voltage level of the delayed clock signal with the voltage level of the inverted clock signal and generate a first comparison clock signal and a second comparison clock signal; and
a buffering unit coupled with the comparing unit, the buffering unit configured to buffer the first comparison clock signal and the second comparison clock signal and output the rising clock signal and the falling clock signal.

3. The clock generating circuit of claim 2, wherein the comparing unit is further configured to generate the first comparison clock signal having a high level and the second comparison clock signal having a low level, when the voltage level of the delayed clock signal is higher than that of the inverted clock signal, and wherein the comparing unit is further configured to generate the first comparison clock signal having a low level and the second comparison clock signal having a high level when the voltage level of the delayed clock signal is lower than that of the inverted clock signal.

4. The clock generating circuit of claim 3, wherein the comparing unit includes:
a first comparator configured to compare the voltage level of the delayed clock signal with the voltage level of the inverted clock signal and generate the first comparison clock signal, and
a second comparator configured to compare the voltage level of the delayed clock signal with the voltage level of the inverted clock signal and generate the second comparison clock signal.

5. The clock generating circuit of claim 4, wherein the first comparator is further configured to generate the first comparison clock signal having a high level, when the voltage level of the delayed clock signal is higher than that of the inverted clock, and wherein the first comparator is further configured to generate the first comparison clock signal having a low level, when the voltage level of the delayed clock signal is lower than that of the inverted clock signal.

6. The clock generating circuit of claim 4, wherein, the second comparator is further configured to generate the second comparison clock signal having a low level, when the voltage level of the delayed clock signal is higher than that of the inverted clock signal, and wherein the second comparator is further configured to generate the second comparison clock signal having a high level, when the voltage level of the delayed clock signal is lower than that of the inverted clock signal.

7. The clock generating circuit of claim 2, wherein the buffering unit includes:
a first buffer configured to buffer the first comparison clock signal to generate the rising clock signal; and
a second buffer configured to buffer the second comparison clock signal to generate the falling clock signal.

8. The clock generating circuit of claim 7, wherein the buffering unit further includes a transition unit configured to simultaneously transition the levels of the rising clock signal and the falling clock signal when the level of at least one of the first comparison clock signal and the second comparison clock signal transitions.

9. The clock generating circuit of claim 8, wherein the first buffer includes:
a first inverter configured to receive the first comparison clock signal; and
a second inverter configured to receive an output signal from the first inverter and generate the rising clock signal, and wherein the second buffer includes:
a third inverter configured to receive the second comparison clock signal; and
a fourth inverter configured to receive an output signal from the third inverter and generate the falling clock signal.

10. The clock generating circuit of claim 9, wherein the transition unit includes:
a fifth inverter; and
a sixth inverter, wherein an input terminal of the fifth inverter and an output terminal of the sixth inverter are commonly connected to a node where the first inverter and the second inverter are connected to each other, and an output terminal of the fifth inverter and an input terminal of the sixth inverter are commonly connected to a node where the third inverter and the fourth inverter are connected to each other.

11. A clock generating circuit of a semiconductor memory apparatus, comprising:
a phase splitter configured to delay a clock signal to generate a delayed clock signal and invert the clock signal to generate an inverted clock signal;
a first clock buffer coupled with the phase splitter, the first clock buffer configured to buffer the delayed clock signal and the inverted clock signal and generate a first rising clock signal and a first falling clock signal; and
a second clock buffer coupled with the phase splitter, the second clock buffer configured to buffer the delayed clock signal and the inverted clock signal to generate a second rising clock signal and a second falling clock signal.

12. The clock generating circuit of claim 11, wherein the first rising clock signal and the second rising clock signal have the same phase, and wherein the first falling clock signal and the second falling clock signal have the same phase.

13. The clock generating circuit of claim 12, wherein the first clock buffer and the second clock buffer are configured such that, when the level of the delayed clock signal transitions, then the levels of the first rising clock signal, the second rising clock signal, the first falling clock signal, and the second falling clock signal simultaneously transition.

14. The clock generating circuit of claim 13, wherein the first clock buffer is configured to output the delayed clock signal as the first rising clock signal, and output the first falling clock signal having a phase opposite to that of the delayed clock signal.

15. The clock generating circuit of claim 14, wherein the first clock buffer includes:
a comparing unit configured to compare the voltage level of the delayed clock signal with the voltage level of the inverted clock signal and generate a first comparison clock signal and a second comparison clock signal; and
a buffering unit coupled with the comparing unit, the buffering unit configured to buffer the first comparison clock signal and the second comparison clock signal and output the first rising clock signal and the first falling clock signal.

16. The clock generating circuit of claim 15, wherein the comparing unit is further configured to generate the first comparison clock signal having a high level and the second comparison clock signal having a low level, when the voltage level of the delayed clock signal is higher than that of the inverted clock signal, and wherein the comparing unit is further configured to generate the first comparison clock signal having a low level and the second comparison clock signal having a high level, when the voltage level of the delayed clock signal is lower than that of the inverted clock signal.

17. The clock generating circuit of claim 15, wherein the buffering unit includes:
a first buffer configured to buffer the first comparison clock signal to generate the first rising clock signal; and
a second buffer configured to buffer the second comparison clock signal to generate the first falling clock signal.

18. The clock generating circuit of claim 17, wherein the buffering unit further includes a transition unit configured to simultaneously transition the levels of the first rising clock signal and the first falling clock signal when the level of at least one of the first comparison clock and the second comparison clock signal transition.

19. The clock generating circuit of claim 13, wherein the second clock buffer is further configured to output the delayed clock signal as the second rising clock signal, and output the second falling clock signal having a phase opposite to that of the delayed clock signal.

20. The clock generating circuit of claim 19, wherein the second clock buffer includes:
a comparing unit configured to compare the voltage level of the delayed clock signal with the voltage level of the inverted clock signal and generate a first comparison clock signal and a second comparison clock signal; and
a buffering unit coupled with the comparing unit, the buffering unit configured to buffer the first comparison clock signal and the second comparison clock signal and output the second rising clock signal and the second falling clock signal.

21. The clock generating circuit of claim 20, wherein the comparing unit is further configured to generate the first comparison clock signal having a high level and the second comparison clock signal having a low level, when the voltage level of the delayed clock signal is higher than that of the inverted clock signal, and wherein the comparing unit is further configured to generate the first comparison clock signal having a low level and the second comparison clock signal having a high level, when the voltage level of the delayed clock signal is lower than that of the inverted clock signal.

22. The clock generating circuit of claim 20, wherein the buffering unit includes:
a first buffer configured to buffer the first comparison clock signal to generate the second rising clock signal; and
a second buffer configured to buffer the second comparison clock signal to generate the second falling clock signal.

23. The clock generating circuit of claim 22, wherein the buffering unit further includes a transition unit configured to simultaneously transition the levels of the second rising clock signal and the second falling clock signal when the level of the first comparison clock signal or the second comparison clock signal transition.
